(19) United States
(12) Patent Application Publication
(10) Pub. No.: US 2023/0192537 A1
(43) Pub. Date: Jun. 22, 2023

(54) METHOD OF TREATING A GLASS SURFACE AND TREATED GLASS ARTICLES

(71) Applicant: Corning Incorporated, Corning, NY (US)

(72) Inventors: Stephanie Marie DeWert, Corning, NY (US); John Albert Gephart, Corning, NY (US); Matthew Stuart Kempton, Corning, NY (US); Christina Marie Laskowski, Painted Post, NY (US); David Andrew Pastel, Horseheads, NY (US); Brandon Thomas Sternquist, Corning, NY (US); Haregewine Tadesse, Corning, NY (US)

(21) Appl. No.: 17/922,501

(22) PCT Filed: May 28, 2021
(86) PCT No.: PCT/US2021/034702

§ 371 Date: Oct. 31, 2022

Related U.S. Application Data
(60) Provisional application No. 63/034,730, filed on Jun. 4, 2020.

(51) Int. Cl. C03C 17/00; C03C 17/32; H10K 59/12

(52) U.S. Cl. CPC C03C 17/002; C03C 17/326; H10K 59/12; C03C 2217/78; C03C 2218/114

(57) ABSTRACT

A substrate with coated edge surfaces, an apparatus for performing the coating, and a method therefor are described. The substrate may include edge surface electrical connectors, wherein the edge coating is coated overtop the edge surface electrical connectors. The apparatus for performing the coating operation includes a rotary fixture configured to facilitate coating of all edge surfaces of a stack of substrate prior to curing of the edge surface coating, wherein according to the method, edge surfaces of one group of corresponding edge surfaces in the stack are coated with a coating material, the rotary fixture is then rotated to position a second group of edge surfaces for coating, and so forth. The coating process is controlled to obtain a consistent overflow onto major surfaces of the stacked substrates.

### CROSS-REFERENCE TO RELATED APPLICATIONS

This is a national stage application under 35 U.S.C. § 371 of International Application No. PCT/US2021/034702 filed on May 28, 2021, which claims the benefit of priority under 35 U.S.C. § 119 of U.S. Provisional Application Ser. No. 63/034,730 filed on Jun. 4, 2020, the content of which is relied upon and incorporated herein by reference in their entireties.

### FIELD

The present disclosure relates to methods of treating a glass surface, and more particularly methods of forming a glass surface comprising a uniformly distributed coating offering high adhesion reliability of a printed pattern.

### TECHNICAL BACKGROUND

MicroLED displays have drawn attention due to self-direct emission, high brightness, high contrast, low power consumption, and longer lifetime compared to TFT-LCD and OLED displays. To make large-size microLED displays, substrates with vias are typically pursued for display concepts that need tiling since the drivers and printed circuit board (PCB) are placed on the backside of the display for seamless assembly of each tile, tile assembly, glass part, etc. Connection between microLEDs on a substrate surface (glass, transparent ceramics or substrates materials) and IC drives or other components on the back can still be realized by wrapped-edge (wrap-around) electrodes.

For seamless tiling, each tile should have an edge profile that aligns well with an immediately-adjacent tile. Therefore, accurate tile alignment should be provided during fabrication and wrap-around electrodes over tile edges should exhibit mechanical reliability. In addition, the wrap-around electrodes need to exhibit mechanical reliability.

### SUMMARY

One approach to enhancing reliability for both the display tile and the wrap-around electrodes is to apply protective edge coatings, durable thin films, or thin laminates. The protective coating may also provide additional optical advantage. For example, applying black or other highly absorbing adhesive coatings, thin films, or hybrid coatings on the electrode-wrapped edges of the display tiles can suppress light reflection. The edge coating may also be a non-absorbing clear or non-clear coating or film.

Accordingly, a display apparatus is disclosed, a glass article comprising a glass substrate including a first major surface, a second major surface opposite the first major surface, and at least one edge surface extending between and connecting the first major surface to the second major surface, the glass substrate further comprising a coating material deposited as a contiguous coating layer on the at least one edge surface and at least a portion of the first major surface or the second major surface along and proximate the at least one edge surface, the coating layer extending an overflow distance on the at least a portion of the first major surface or the second major surface in a range from equal to or greater than 25 micrometers to equal to or less than about 170 micrometers. A thickness of the coating layer can be equal to or less than about 100 micrometers, for example equal to or less than about 50 micrometers, equal to or less than about 10 micrometers, or equal to or less than about 4 micrometers. The coating material can comprise an epoxy. A thickness of the glass substrate is in a range from about 300 micrometers to about 1.3 millimeters.

In some embodiments, a bulk resistivity of the coating material can be equal to or greater than about 1×10⁸ ohm, for example equal to or greater than about 1×10¹⁵ ohm.

In some embodiments, a surface roughness Sa of the coating layer can be equal to or less than about 250 nanometers.

In some embodiments, an optical density of the coating layer can be equal to or greater than about 1.8, for example, equal to or greater than about 2, such as in a range from equal to or greater than about 2 to equal to or less than about 2.5.

In some embodiments, the at least one edge surface can comprise a plurality of edge surfaces, the contiguous coating layer coating each edge surface.

The at least one edge surface can comprise an arcuate surface.

The glass article may further comprise an electrical conductor extending across the at least one edge surface of the glass substrate from the first major surface to the second major surface the coating layer disposed over the electrical conductor. In some embodiments, an electronic device can be deposited on the first major surface and in electrical communication with the electrical conductor. The electronic device may, for example, comprise an electroluminescent element, such as a light emitting diode.

In other embodiments, a method of coating a glass substrate is described, comprising positioning a plurality of glass substrates and a plurality of spacers in an alternating relationship to form a substrate stack, each glass substrate comprising a first major surface, a second major surface, a first edge surface extending between and connecting the first major surface and the second major surface, and a second edge surface extending between and connecting the first and second major surfaces, and clamping the substrate stack between a first platen and a second platen in a fixture. The fixture can be mounted beneath a screen, the clamped substrate stack rotatable in the fixture about an axis of rotation orthogonal to the first major surface of each glass substrate, and the clamped stack oriented to a first orientation. A coating material can then be applied to the screen. Once the screen is wetted with the coating material, the method further comprises forcing a squeegee onto the screen and deflecting the screen toward the first edge surfaces, traversing the squeegee across the screen in a first direction orthogonal with the axis of rotation from a start position to a stop position to apply the coating material to the first edge surfaces, and returning the squeegee to the start position. Once the first edge surfaces are coated, the method may further comprise rotating the substrate stack to a second orientation, forcing the squeegee onto the screen and deflecting the screen toward the second edge surfaces, and traversing the squeegee in the first direction across the screen from the start position to the stop position to apply the coating material to the second edge surfaces. In some embodiments, the first orientation can be orthogonal to the second orientation

The coating material can be applied to at least a portion of at least one of the first major surface or the second major surface of each glass substrate simultaneous with applying the coating to the first edge surface. An overflow distance on the at least a portion of the first major surface or the second major surface in a range from equal to or greater than 25 micrometers to equal to or less than about 170 micrometers.

In some embodiments, each glass substrate can comprise at least one electrical conductor extending across the first edge surface from the first major surface to the second major surface, and the coating material is applied over the at least one electrical conductor.

Each of the first platen and the second platen comprises a first major surface, a second major surface, and a first edge surface extending between and connecting the first major surface and the second major surface, the first edge surface of the first platen and the first edge surface of the second platen defining a first plane. The first edge surfaces of the glass substrates can extend outward from the first plane a distance in a range from about 10 micrometers to about 100 micrometers.

In some embodiments, each spacer comprises a first major surface, a second major surface, and a first edge surface extending between and connecting the first major surface and the second major surface of the respective spacer, and a distance between the first edge surface of one of the glass substrates and the first edge surface of a spacer adjacent to the one of the glass substrates can be in a range from about 1 mm to about 3 mm.

A thickness of each spacer can be in a range from about 1 millimeter to about 20 millimeters.

In some embodiments, the coating material applied to the first edge surface of each glass substrate is not cured prior to the applying the coating material to the second edge surface of each substrate.

In some embodiments, each glass substrate in the substrate stack comprises at least three edge surfaces, and the method further comprises coating each edge surface of each glass substrate with the coating material and curing the coating material after the coating material has been applied to each edge surface.

Additional features and advantages of the embodiments disclosed herein will be set forth in the detailed description that follows, and in part will be clear to those skilled in the art from that description or recognized by practicing the embodiments described herein, including the detailed description which follows, the claims, as well as the appended drawings.

It is to be understood that both the foregoing general description and the following detailed description present embodiments intended to provide an overview or framework for understanding the nature and character of the embodiments disclosed herein. The accompanying drawings are included to provide further understanding and are incorporated into and constitute a part of this specification. The drawings illustrate various embodiments of the disclosure, and together with the description explain the principles and operations thereof.

### BRIEF DESCRIPTION OF THE DRAWINGS

FIG. 1 is a side cross-sectional view of an exemplary display apparatus;

FIG. 2 is a top view of the display apparatus of FIG. 1;

FIG. 3 is a perspective view of an exemplary display tile useable in the manufacture of the display apparatus of FIGS. 1 and 2 showing pixel elements and edge surface connectors;

FIG. 4 is a front view of an exemplary flex circuit that can be used to provide edge surface connectors;

FIG. 5 is a cross-sectional view of the flex circuit of FIG. 4;

FIG. 6 is a cross-sectional perspective view of a portion of an edge of an exemplary display tile;

FIG. 7 is a cross-sectional view of an edge of an exemplary display tile with a planar edge surface orthogonal to the major surfaces of the tile substrate;

FIG. 8 is a cross-sectional view of an edge of an exemplary display tile with a chamfered edge surface;

FIG. 9 is a top view of a tile substrate comprising rounded corners;

FIG. 10 is an elevational view of an exemplary apparatus for applying a coating material to a display tile, for example a stack of display tiles;

FIG. 11 is a cross-sectional view of a stack of display tiles including spacers arranged between the display tiles in an alternating arrangement;

FIG. 12 is a cross-sectional view of a portion of a stack of display tiles wherein the tile substrates comprise arcuate edge surfaces;

FIG. 13 is a cross sectional view of a rotary fixture useable with the apparatus of FIG. 10;

FIG. 14 is a perspective view of a stacking jig for assembling a stack of display tiles in preparation for edge coating application;

FIG. 15 is a perspective view of the stacking jig of FIG. 14 showing display tiles and spacers positioned in the jig;

FIG. 16 is a perspective view of a template block useable to obtain consistent display tile edge surface spacing relative to spacer edge surfaces;

FIG. 17 is an elevational view of coating material being applied to edge surfaces of a stack of display tiles via screen printing;

FIG. 18 is a chart showing average coating material overflow onto major surfaces of the tile substrate as a function of spacer thickness;

FIG. 19 is a chart showing average coating material overflow onto major surfaces of the tile substrate as a function of edge surface chamfer;

FIG. 20 is a cross-sectional side view of a stack of display tiles with uneven edge surface heights;

FIG. 21 is a chart showing the effects on average coating material overflow for the uneven edge surface heights of FIG. 20;

FIG. 22 is a cross-sectional side view of another stack of display tiles with chamfered edge surfaces and uneven edge surface heights;

FIG. 23 is a chart showing the effects on average coating material overflow for the uneven edge surface heights of FIG. 22; and

FIG. 24 is a chart showing average coating material overflow as a function of printing screen condition.

### DETAILED DESCRIPTION

Reference will now be made in detail to embodiments of the present disclosure, examples of which are illustrated in the accompanying drawings. Whenever possible, the same reference numerals will be used throughout the drawings to refer to the same or like parts. However, this disclosure can be embodied in many different forms and should not be construed as limited to the embodiments set forth herein.

As used herein, the term “about” means that amounts, sizes, formulations, parameters, and other quantities and characteristics are not, and need not be, exact, but may be approximate and/or larger or smaller, as desired, reflecting tolerances, conversion factors, rounding off, measurement error and the like, and other factors known to those of skill in the art.

Ranges can be expressed herein as from “about” one value, and/or to “about” another value. When such a range is expressed, another embodiment includes from the one value to the other value. Similarly, when values are expressed as approximations by use of the antecedent “about,” it will be understood that the value forms another embodiment. It will be further understood that the endpoints of each of the ranges are significant both in relation to the other endpoint, and independently of the other endpoint.

Directional terms as used herein—for example up, down, right, left, front, back, top, bottom—are made only with reference to the figures as drawn and are not intended to imply absolute orientation.

Unless otherwise expressly stated, it is in no way intended that any method set forth herein be construed as requiring that its steps be performed in a specific order, nor that with any apparatus, specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an” and “the” include plural references unless the context clearly dictates otherwise. Thus, for example, reference to “a” component includes aspects having two or more such components, unless the context clearly indicates otherwise.

The word “exemplary,” “example,” or various forms thereof are used herein to mean serving as an example, instance, or illustration. Any aspect or design described herein as “exemplary” or as an “example” should not be construed as preferred or advantageous over other aspects or designs. Furthermore, examples are provided solely for purposes of clarity and understanding and are not meant to limit or restrict the disclosed subject matter or relevant portions of this disclosure in any manner. It can be appreciated that a myriad of additional or alternate examples of varying scope could have been presented but have been omitted for purposes of brevity.

As used herein, the terms “comprising” and “including”, and variations thereof, shall be construed as synonymous and open-ended, unless otherwise indicated. A list of elements following the transitional phrases comprising or including is a non-exclusive list, such that elements in addition to those specifically recited in the list may also be present.

The terms “substantial,” “substantially,” and variations thereof as used herein are intended to represent that a described feature is equal or approximately equal to a value or description. For example, a “substantially planar” surface is intended to denote a surface that is planar or approximately planar. Moreover, “substantially” is intended to denote that two values are equal or approximately equal. In some embodiments, “substantially” may denote values within about 10% of each other, such as within about 5% of each other, or within about 2% of each other.

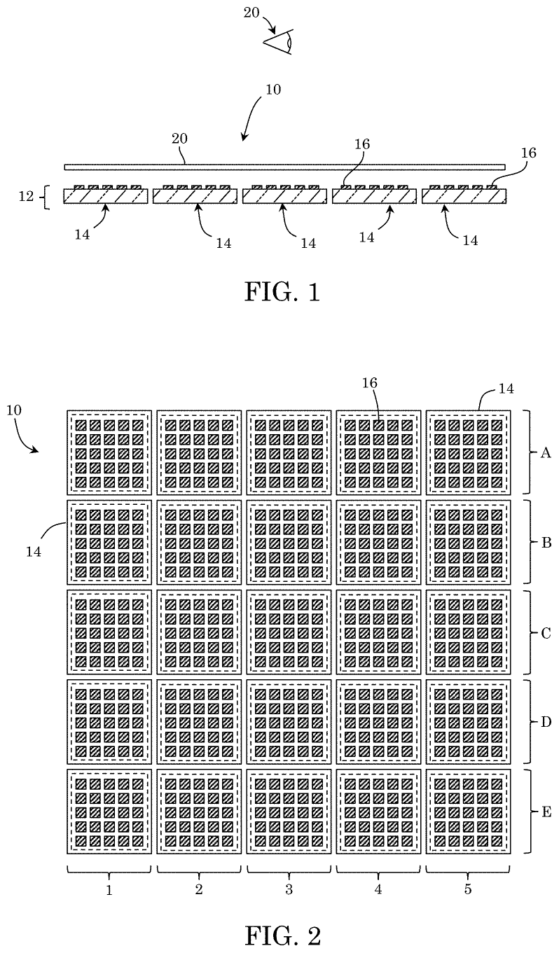

FIGS. 1 and 2 illustrate an exemplary display apparatus 10 comprising display panel 12. Display panel 12 comprises a plurality of display tiles 14 arranged in an array, for example a rectangular array comprising a plurality of rows of display tiles and a plurality of columns of display tiles orthogonal to the rows of display tiles. For example, FIG. 2 depicts for illustrative purposes and not limitation a display panel 12 comprising five rows A-E of display tiles 14 and five columns 1-5 of display tiles 14. In other embodiments, the number of display tiles 14 can comprise greater than or less than five rows or greater than or less than five columns. For example, display apparatus 10 can comprise tens or more rows and/or columns of display tiles. Moreover, there is not requirement that the number of columns of display tiles equal the number of rows of display tiles. Each display tile 14 comprises a plurality of pixel elements 16. Pixel elements 16 may be arranged in any number of geometric arrays, for example rectangular (e.g., square) arrays, triangular arrays, hexagonal arrays, and the like.

Display apparatus 10 may further comprise a cover plate 18 positioned between display panel 12 and a viewer 20 of the display apparatus. That is, display cover plate 18 is positioned in front of display panel 12 relative to viewer 20. Cover plate 18 may be a glass plate or a polymer (e.g., plastic) cover plate. In some embodiments, cover plate 18 may be a laminate cover plate comprising multiple layers, for example a combination of glass and polymer layers. In some embodiments, cover plate 18 may include one or more films, for example an anti-reflection film.

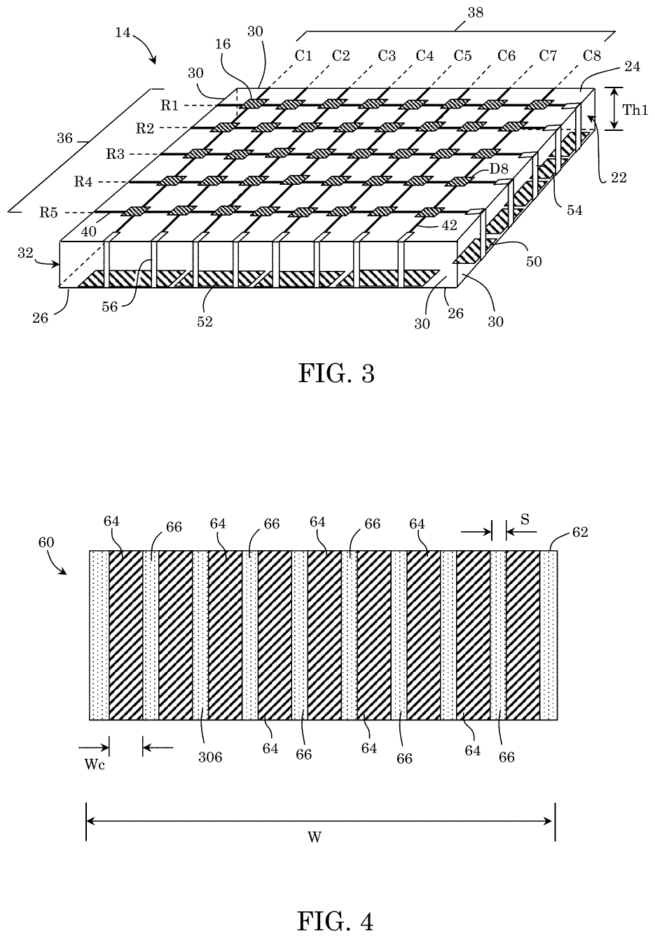

Referring now to FIG. 3, an individual display tile 14 according to one or more embodiments can comprise a tile substrate 22 of any suitable material, for example, a polymeric substrate or a glass-based substrate having any desired size and/or shape appropriate to produce a display tile. As used herein, the term “glass-based substrate” is used in the broadest sense to include any object made wholly or partly of glass. For example, glass-based substrates can include laminates of glass and non-glass materials, laminates of glass and crystalline materials, or laminates of glass and glass-ceramics (including an amorphous phase and a crystalline phase). A glass-based tile substrate 22 can comprise any glass-based material known in the art for use in display devices. For example, a glass-based tile substrate 22 may comprise aluminosilicate, alkali-aluminosilicate, borosilicate, alkali-borosilicate, aluminoborosilicate, alkali-aluminoborosilicate, soda lime, or other suitable glasses. Non-limiting examples of commercially available glasses suitable for use in a glass-based tile substrate can include, for example, EAGLE XG®, Lotus™, and Willow® glasses from Corning Incorporated.

Tile substrate 22 comprises first major surface 24 and second major surface 26, which major surfaces may, in various embodiments, be planar or substantially planar, e.g., substantially flat. First major surface 24 and second major surface 26 may, in various embodiments, be parallel or substantially parallel (e.g., within manufacturing tolerances). Tile substrate 22 further comprises an edge surface 30 extending between and connecting first major surface 24 and second major surface 26, edge surface 30 defining an outer perimeter of tile substrate 22. By way of a non-limiting example, tile substrate 22 may comprise a rectangular (e.g., square), or rhomboid plate with four edge surfaces, such as four edge surfaces 30 joined at right angles (orthogonal) to each other as shown in FIG. 3, although other shapes and configurations are intended to fall within the scope of the disclosure including edge surfaces with one or more curvilinear portions. In other embodiments, tile substrate 22 may comprise fewer than four edge surfaces 30, e.g., a triangle. In still other embodiments, tile substrate 22 may comprise a single edge surface 30, e.g., tile substrate 22 can be circular or other arcuate shape. For tile substrates having three or more distinct edge surfaces, adjacent edge surfaces intersect at corners 32. Accordingly, a tile substrate with four edge surfaces 30 comprises four corners 32.

In certain embodiments, tile substrate 22 can have a thickness Thl between first major surface 24 and second major surface 26 less than or equal to about 3 mm, for example, in a range from about 0.1 mm to about 3 mm, from about 0.1 mm to about 2.5 mm, from about 0.3 mm to about 2 mm, from about 0.3 mm to about 1.5 mm, from about 0.3 mm to about 1 mm, from about 0.3 mm to about 0.7 mm, or in a range from about 0.3 mm to about 0.5 mm, including all ranges and subranges therebetween.

In embodiments, first major surface 24 of tile substrate 22 can comprise pixel elements 16 deposited thereon and arranged in an array, for example a plurality of rows 36 of pixel elements 16 and a plurality of columns 38 of pixel elements 16. For example, the exemplary display tile shown in FIG. 3 depicts five rows of pixel elements 16 (R1-R5) and eight columns of pixel elements 16 (C1-C8).

As is understood in the art, different types of displays can utilize different types of pixel elements to provide a display image. For example, in an organic light emitting diode (OLED) display, a pixel element can comprise rows and/or columns of “emitters” and thin film transistors (TFTs) connected by row drivers and column drivers that activate the pixel elements, while the pixel element in liquid crystal displays (LCD) may comprise rows and columns of liquid crystal (LC) light valves and transistors connected by row drivers and column drivers that activate the pixel elements. Accordingly, pixel elements are the components required for the functioning of individual pixels in the display and can include light emitting elements (e.g., light emitting diodes) or light valves and TFTs. The descriptions provided herein are simplified such that each pixel element is illustrated comprising one color pixel, whereas in reality each pixel element may be comprised of one or more subpixels (e.g., red, green and blue subpixels). Individual pixel elements can be addressed by a unique row and column combination utilizing known technology.

Each row 36 of pixel elements 16 can be connected by a row electrical trace 40, and each column 38 of pixel elements 16 can be connected by a column electrical trace 42. As used herein, an electrical trace is an electrical conductor configured to direct electrical current to and from electrical components of the display apparatus. Electrical traces can be applied to a major surface of the tile substrate, for example, by depositing an electrical conductor material on a surface of a tile substrate and forming the electrical traces by photolithography wherein selected portions of the electrical conductor material are covered by a masking material and unneeded electrical conductor material removed with an etchant. However, other methods of forming electrical traces as are known in the art may be used. For example, in further embodiments, electrical traces may be applied, such as with an adhesive. In some embodiments, electrical trances may comprise wires.

While the exemplary display tile shown in FIG. 3 depicts five rows of pixel elements 16, and eight columns of pixel elements 16, in other embodiments, an individual display tile 14 may comprise hundreds or thousands of pixel elements 16. The row and column electrical traces 40, 42 intersect at selected pixel elements 16. Thus, there is an array of pixel elements 16 containing pixel elements connected to separate row and column electrodes such that each row electrical trace 40 and each column electrical trace 42 intersects at a unique addressable pixel element. A tile substrate according to one or more embodiments can comprise at least one row driver 50 configured to electrically activate at least one pixel element 16 in one or more rows 36 of pixel elements 18 and at least one column driver 52 configured to activate at least one pixel element 16 in one or more columns 38 of pixel elements. The row drivers 50 and the column drivers 52 can be located on second major surface 26 opposite first major surface 24. However, in other embodiments, row drivers 50 and column drivers 52 can be located on a separate structure such as on a separate substrate (not shown) or another suitable structure.

As will be appreciated, row drivers 50 and column drivers 52 must be connected to the row electrical traces 40 and the column electrical traces 42 to activate pixel elements 16. Accordingly, a plurality of row edge connectors 54 may be provided, wherein each row edge connector 54 can be wrapped around an edge surface 30 and electrically connect through a row electrical trace 40 a row 36 of pixel elements 16 and a row driver 50. Display tile 14 may further comprise a plurality of column edge connectors 56, wherein each column edge connector 56 can be wrapped around an edge surface 30 and electrically connect through a column electrical trace 42 a column 38 of pixel elements 16 and a column driver 52. As used herein, a row and column edge connectors comprises an electrical conductor that wraps around an edge of the tile substrate. In the embodiment shown, each row driver 50 connects one row 36 of row electrical traces 40 to row pixel elements, and each column driver 52 connects two columns of column electrical traces 42 to column pixel elements. However, the depicted arrangement is for illustration purposes, and the disclosure is not limited to any particular number of row drivers, column drivers or number of row electrical traces or column electrical traces respectively driven by the row drivers and column drivers. For example, the row and column edge connectors can exist on one or more edge surfaces 30 based on the specific display apparatus design and layout.

Display tile 14 can be free of a bezel around the outer perimeter of tile substrate 22. To achieve a seamless display apparatus, a pixel pitch (distance between nearest adjacent pixel elements) across a tile-to-tile seam should be approximately matched to a comparable distance between adjacent pixel elements within a single display tile. For example, the distance between adjacent pixel elements can be equal to or less than about 10 millimeters (mm), equal to or less than about 5 mm, equal to or less than about 3 mm, equal to or less than about 1 mm, equal to or less than about 0.5 mm, or equal to or less than about 0.3 mm from an edge of the display tile substrate. Pixel elements on one display tile can then be registered to adjacent pixel elements on an adjacent display tile with a placement error equal to or less than about 50%, equal to or less than about 30%, equal to or less than about 10%, or equal to or less than about 5% of a pixel pitch (distance between adjacent pixels on a display tile).

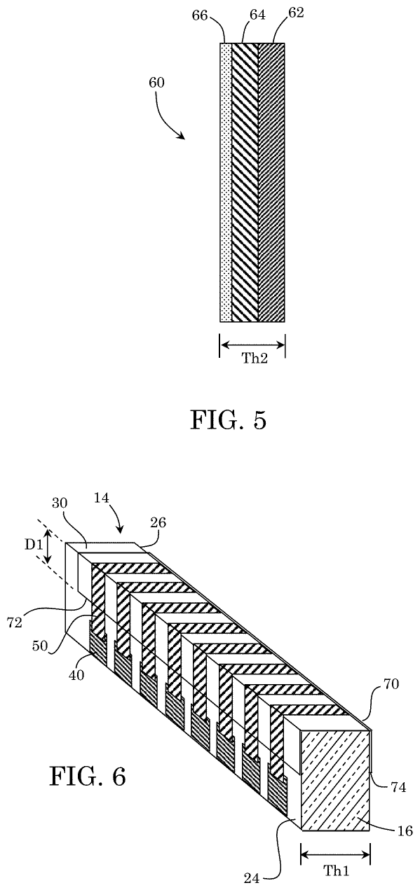

Any suitable connector type can be utilized to provide row edge connectors 54 and column edge connectors 56. Also, the row and column edge connectors need not be of the same type or design. In one or more embodiments, a row edge connector 54 and/or a column edge connector 56 can comprise a flex circuit 60 shown in FIGS. 4 and 5. An exemplary flex circuit 60 may comprise a flexible polymeric film 62 and an electrical conductor 64. In the depicted embodiment, a plurality of electrical conductors 64 are shown arranged in rows. Flex circuit 60 may further comprise an adhesive 66 that can adhere flex circuit 60 to an edge surface 30 of tile substrate 22. In the embodiment shown, adhesive 66 can be an adhesive layer integrally formed with the flex circuit. In some embodiments, flex circuit 60 may comprise flexible polymeric film 62 and electrical conductor(s) 64, and an adhesive may be separately applied to an edge surface of the tile substrate or the flex circuit. Flex circuit 60 can have a total thickness Th2 in a range from about 10 μm to about 150 μm, for example, in a range from about 10 μm to about 50 μm or in a range from about 10 μm to about 20 μm. Suitable materials for polymeric film 62 can include, but are not limited to, materials selected from the group consisting of polyimide, polyester, polyethylene naphthalate (PEN), polyethylene terephthalate (PET), and polyether ether ketone (PEEK). Adhesive 66 can comprise a pressure sensitive adhesive, for example, a polyimide, an acrylic, an acrylate, ethylene vinyl acetate, butyl rubber, nitrile, or silicone. Flex circuit 60 can also be adhered to edge surface 30 by use of a curable or liquid adhesive. Electrical conductor 64 can be selected from copper and silver, or other metals or other electrically-conductive material, and can be formed by any suitable method, such as deposition, plating, printing, thick films, etc. Examples of conductive materials not based on deposited films can include solution-based materials such as a silver-containing ink. Overall dimensions of flex circuit 60 can vary and ultimately will be determined by the size of the display tile. A suitable width “W” can be in a range from about 10 mm to about 500 mm, for example in a range from about 50 mm to about 100 mm, and the conductors can have a width “W_{c}” in a range from about 20 μm to about 500 μm, for example about 100 μm, although other widths are contemplated. Spacing “S” between each conductor can be in a range from about 10 μm to about 500 μm, for example 50 μm.

Turning to FIG. 6 depicting a portion of a first edge surface 30 of an exemplary display tile 14, in various embodiments a coating material can be applied to an edge surface 30 of display tile 14 to provide mechanical and electrical protection to the edge surface and/or the row and/or column edge connectors 54, 56. The coating material can be optically clear, translucent, or opaque as needed. For example, in some embodiments, the coating material can comprise a pigment to reduce light reflection from the edge surfaces of the display tiles, for example carbon black or a metallic particulate (e.g., a metallic oxide). The coating material can be thermally curable, UV (ultraviolet) curable, or, in some embodiments, the coating material may be cured with both a UV-cure and a thermal cure. The coating material can be selected to have a bulk resistivity equal to or greater than about 1×10⁸ ohms (Ω), for example equal to or greater than about 1×10¹⁵ Ω. The bulk resistivity is determined by depositing the selected coating material on a portion of a silicon wafer, curing the coating material, then coating the cured coating material with a silver-containing ink and curing the silver containing ink to obtain a silver layer on the coating material. The bulk resistivity is measured through a thickness of the coating material with a resistance meter. One probe of the resistance meter is contacted on the uncoated portion of the silicon wafer and the other probe is contacted on the silver layer overtop the coating layer. The coating may include hybrid materials (polymer-nano (micro) composites, e.g., silicates, nanomaterials, and/or silsesquioxanes), resins with solvents, dispersed micro-particles in solvent systems, and the like. The base resin may be acrylate- or urethane-based for chemical and moisture resistance and form a coating layer with low shrinkage properties. The coating material can, for example, comprise an epoxy resin. The epoxy resin can be selected for hardness, good adhesion and excellent abrasion properties: silicone-based epoxy resins can be selected for corrosion resistance; polyimide-based epoxy resins can be used for high temperature resistance; and poly(p-xylylene)-based epoxy resins (e.g., parylene) can be applied for good electrical performance. Coating layer 70 may contain one or more of these epoxy resins and particle options in one or more layers. Other suitable polymers can include polysulfones, polyetherimides, or polyphthalamides.

In various embodiments, the coating material can be disposed over row and column edge connectors 54, 56 on edge surfaces 30. More specifically, the coating material can form a contiguous coating layer 70 over the one or more edge surfaces of the display substrate. As used herein, “contiguous” means the coating layer is uninterrupted, with no gaps or discontinuities. In various embodiments, the coating material may also be applied to major surfaces 24 and/or 26 of display tile 14 such that at least a portion of the first major surface 24 and/or the second major surface 26 of tile substrate 22 comprises a coating layer 70 contiguous with the coating layer 70 disposed on an edge surface of the tile substrate. That is, coating layer 70 can be disposed on an edge surface 30 and can extend over the edge surface onto the connected major surface (e.g., first and/or second major surfaces 24 or 26) along a length of the respective edge surface. This extension of coating layer 70 onto one or both major surfaces 24 or 26 of the display tile is termed “overflow.” In various embodiments, coating layer 70 can comprise terminal edges 72 and 74 corresponding to the cessation of overflow on first and second major surfaces 24, 26, respectively. For example, in the absence of overflow, the terminal edges of a well-applied coating material correspond to the edges of the coating layer at the intersection of the edge surface 30 and the first major surface 24, and/or the intersection of the edge surface 30 and the second major surface 26. However, in the presence of overflow, a terminal edge of the coating layer corresponds to the line demarking (e.g., separating) that portion of the display tile with a coating layer and that portion of the display tile that is uncoated. That is, terminal edges 72, 74 are the edges of the coating layer where the flow of coating material stopped on the respective display tile major surface. The extent of the overflow, D1, defines a distance of the overflow measured from the intersection of an edge surface 30 and the major surface to the corresponding terminal edge along a line orthogonal to the intersection. While the description above relates to a single edge surface 30, a coating layer can be applied to each edge surface 30 of a display tile in similar manner. The coating layer overflow distance D1 can be in a range from greater than zero μm to equal to or less than about 170 μm, for example in a range from equal to or greater than 25 μm to equal to or less than about 150 μm. However, in further embodiments, D1 in excess of 170 μm has been achieved. In various embodiments, an optical density of the coating layer can be equal to or greater than about 1.8 as measured with a Gretag Macbeth D200-II optical density meter. For example, an optical density of the coating layer can be equal to or greater than about 2, such as in a range from about 2 to equal to or less than about 2.5.

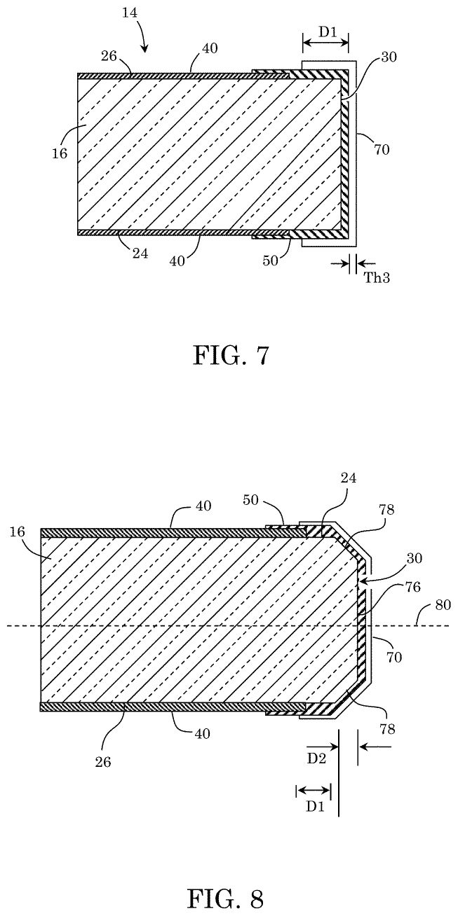

A thickness Th3 (see FIG. 7) of coating layer 70 can be equal to or less than about 100 μm, for example equal to or less than about 80 μm, such as equal to or less than about 60 μm, equal to or less than about 50 μm, equal to or less than about 30 μm, equal to or less than about 10 μm, equal to or less than about 4 μm, or in some embodiments, equal to or less than about 1 μm. In various embodiments, an average areal surface roughness Sa of coating layer 70 can be equal to or less than about 250 nm as measured with a Zygo NewView 8000 optical surface profiler. For example, areal surface roughness Sa can be equal to or less than about 200 nm, such as equal to or less than about 150 nm.

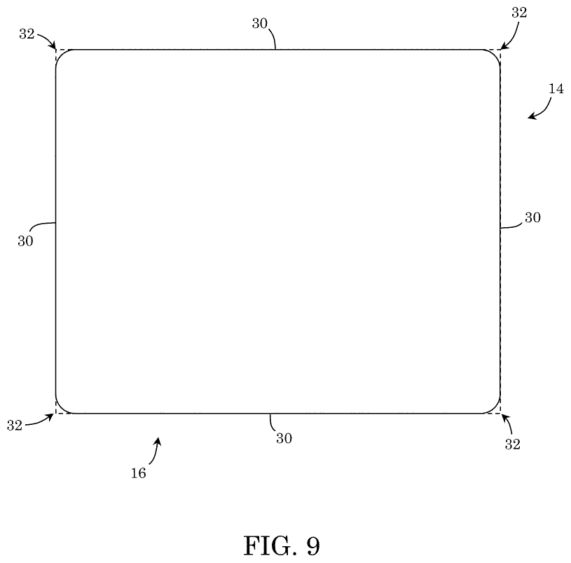

In some embodiments, edge surface 30 can be substantially planar and orthogonal to first and second major surfaces 24, 26 as shown in FIG. 7. However, in other embodiments, edge surface 30 can be chamfered as shown in FIG. 8. The chamfered edge surface 30 of FIG. 8 comprises end portion 76 connected to first and second major surface 24, 26 by angled (chamfered) portions 78. Chamfered edge surfaces can help prevent damage to a printing screen during application of the coating material to the edge surfaces. In some embodiments, edge surfaces may be arcuate or include arcuate portions. Additionally, in some embodiments, corners 32 of the tile substrates (where one edge surface intersects an adjacent edge surface) can be rounded (e.g., radiused) as illustrated in FIG. 9. Like chamfering, rounding corners of the tile substrates can avoid sharp projections and prevent damage to screen printing equipment, e.g., the printing screen.

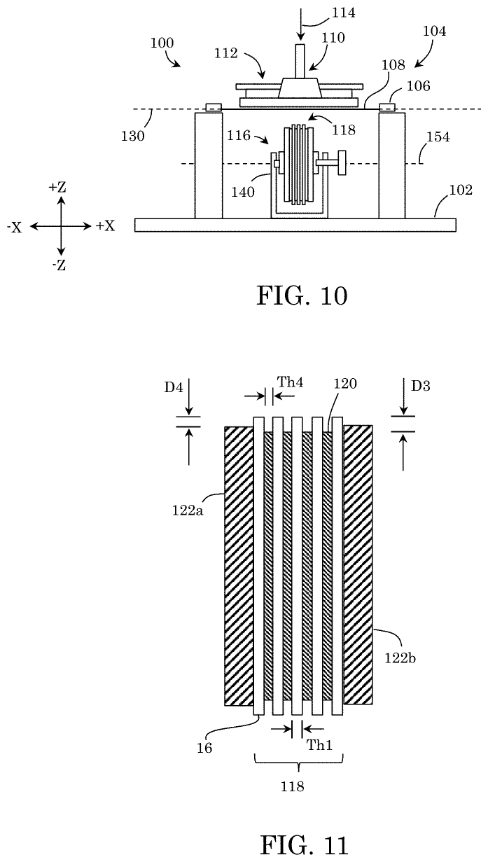

Referring now to FIG. 10, an exemplary coating apparatus 100 is shown. Coating apparatus 100 can comprise a base 102, a screen assembly 104 comprising frame 106 and screen 108 mounted therein, a coating material delivery system 110 for delivering coating material to screen 108, a squeegee assembly 112 for extruding coating material 114 through screen 108 onto a workpiece (e.g., a display tile), and a rotary fixture 116 configured to hold a stack 118 of display tiles 14 and orient the stack 118 of display tiles for application of coating material 114 to edge surfaces of the display tiles. Screen 108 may be any screen suitable for screen printing, however, non-metallic screens are more damage-resistant when used to screen print a coating layer on edge surfaces of display tiles, particularly glass-based display tiles. In various embodiments, a polymer screen can be used, for example a polymer screen comprising polyester and/or nylon mesh, to provide greater resilience to deformation compared to stainless steel mesh, thereby minimizing screen tearing.

As best shown in FIG. 11, stack 118 comprises a plurality of tile substrates 16 configured with intervening spacers 120 in an alternating arrangement. Edge surfaces 30 of the plurality of tile substrates 16 can be aligned to be substantially parallel and substantially coplanar. By way of example and not limitation, FIG. 11 depicts a stack 118 of rectangular display tiles 14 positioned between two opposing platens 122a, 122b, each display tile 14 comprising four edge surfaces 30. Each edge surface 30 of the rectangular display tiles 14 is substantially parallel and substantially coplanar with corresponding edge surfaces of the remaining display tiles in the stack. By corresponding what is meant is that stack 118 represents, generally, a geometric shape, e.g., a rectangular cuboid, for example, a square (regular) cuboid. Accordingly, each face of the shape, such as a cuboid by way of example, can be represented generally by a plane, and the edge surfaces of the constituent tile substrates comprising a particular face of the stack represent “corresponding” edge surfaces in that they are located at the same face of the cuboid. Additionally, in this context “substantially” means the display substrates are within equal to or less than about 100 μm of being parallel and coplanar. That is, no display substrate edge surface is higher than or lower than 100 μm from an adjacent display substrate, and the total difference between the highest end face and the lowest end face is no greater than 200 μm.

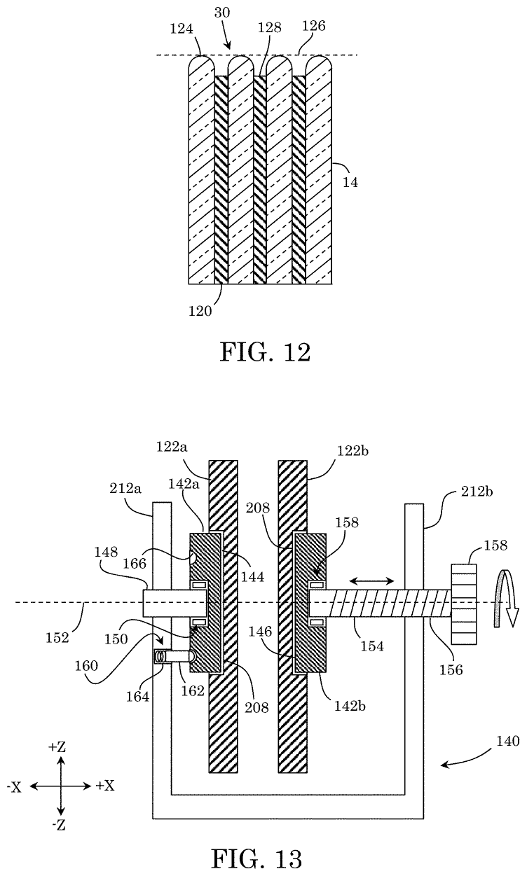

In the event corresponding edge surfaces are curved, each corresponding edge surface 30 includes an apex extending lengthwise along a length of the edge surface, wherein the display tiles are arranged in the stack such that the apexes of the plurality of corresponding parallel edge surfaces define a plane. This can be better understood with the aid of FIG. 12 showing a side of a plurality of display substrates arranged in a stack comprising a plurality of arcuate edge surfaces 30. Each arcuate edge surface 30 on the illustrated side of the stack comprises an apex 124 extending along the length of the edge surface. The collection of apexes representing all of the tile substrates in the stack in turn defines a plane 126, such that a planar article (e.g., a flat glass plate) laid across the edge surfaces 30 contacts each edge surface along a full extent of each apex line. Conversely, coplanar in this context does not mean the edge surface 30 itself need necessarily be planar, although in some embodiments the edge surfaces 30 may be planar. Thus, in this context and in respect of the previous embodiment, coplanar means that corresponding edge surfaces are straight and lie within a plane.

For clarity, the apex of a planar edge surface, as depicted in FIG. 7, is the entire edge surface, whereas the apex of a chamfered edge surface, as depicted in FIG. 8, comprises the most-projected portion. Accordingly, the apex need not be considered a line along the edge surface but can include a surface.

As described above, spacers 120 can be positioned between display tiles 14 within a stack 118. For example, spacers 120 can be sized and configured such that when interposed in stack 118, edge surfaces 128 of spacers 120 are recessed a distance D3 relative to corresponding edge surfaces 30 of adjacent display tiles (see FIG. 11). In embodiments, distance D3 can be uniform for each face of the stack wherein both tile substrate and spacer edge surfaces 30, 128 are exposed. Distance D3 can be, for example, in a range from about 0.2 mm to about 3 mm, for example from about 1 mm to about 3 mm, such as 1.5 mm. Spacer thickness Th4 can be in a range from about 0.1 mm to about 0.5 mm, for example in a range from about 0.2 mm to about 0.5 mm, such as from about 0.3 mm to about 0.5 mm. Spacer thickness is measured, for example using calipers and/or a micrometer, along a normal to one or both major surfaces of a spacer. Spacers 120 can be formed from a variety of materials. For example, in some embodiments, spacers 120 can comprise glass, while in other embodiments, spacers 120 can comprise polymer. Polymer spacers can be easier to separate from display substrates after the coating material has been applied. However, unless the polymer is sufficiently heat resistant, it may be necessary to separate the individual display substrates from the stack prior to curing (if the coating material is a thermally cured material), whereas a stack comprising glass spacers may be transferred directly from deposition of the coating material to a curing oven before separation of the individual display substrates, thereby reducing process steps.

Rotary fixture 116 can be configured to hold stack 118 in a predetermined orientation relative to a reference plane, for example a plane of base 102. Screen assembly 104 can then be adjusted such that a plane of screen 108 is parallel with an upward facing face of the stack. Plane 130 is defined between attachment points of screen 108 to frame 106. For example, rotary fixture 116 can be configured to hold stack 118 such that a face of the stack (corresponding edge surfaces 30) is held substantially parallel to base 102, and more particularly, so that corresponding edge surfaces of the display substrates comprising stack 118 facing screen 108 are substantially parallel with base 102. As best seen in FIG. 13, rotary fixture 116 can comprise support member 140, for example a U-shaped support member, and a first clamping pad 142a rotatably coupled to support member 140, first clamping pad 142a comprising a clamping surface 144. Rotary fixture 116 may further comprise a second clamping pad 142b rotatably coupled to support member 140, second clamping pad 142b comprising a second clamping surface 146 facing first clamping surface 144. First clamping pad 142a can be rotatably coupled to support member 140, for example by axle 148 extending from first clamping pad 142a. In the embodiment depicted in FIG. 13, first clamping pad 142a can be rotatably coupled to support member 140 with first bearing assembly 150, thereby allowing free rotation of first clamping pad 142a relative to support member 140 about axis of rotation 152. While first clamping pad 142a is shown coupled to axle 148 via first bearing assembly 150 (first bearing assembly 150 contained in or mounted to first clamping pad 142a, in further embodiments, axle 148 can be rigidly fixed to clamping pad 142a, or formed integrally therewith, and axle 148 rotatably coupled to support member 140 via a bearing assembly contained in or mounted on support member 140.

In some embodiments, as further shown in FIG. 13, second clamping pad 142b can be coupled to support member 140 by threaded rod 154 (e.g., screw or bolt) arranged in a complementary threaded socket or bore on support member 140 such that rotation of threaded rod 154 moves second clamping pad 142b along longitudinal axis 156 of threaded rod 154, i.e., toward or away from opposing first clamping pad 142a. Longitudinal axis 156 can be coaxial with axis of rotation 152 and reference to either is reference to both. In some embodiments, threaded rod 154 may be rotated by hand (e.g., via knob 159), while in other embodiments, threaded rod 154 may be rotated by a motor (e.g., a stepper motor, a motor coupled to a reduction gear assembly, etc., not shown). In still other embodiments, threaded rod 154 can comprise a piston-driven assembly, wherein second clamping pad 142b is moved along axis of rotation 152 by a cylinder, e.g., a pneumatic cylinder. In some embodiments, second clamping pad 142b can be rotatably coupled to threaded rod 154, for example by second bearing assembly 158.

Rotary fixture 116 may further comprise a detent mechanism 160, for example a spring-loaded detent arranged in a bore and configured to hold first clamping pad 142a in a predetermined orientation while still allowing first clamping pad 142a to rotate about axis of rotation 152 if sufficient rotational force is applied to first clamping pad 142a. As used herein, a detent mechanism is a mechanism (such as comprising a detent—a catch, pin, dog, or spring-operated ball, for example) for positioning and holding one mechanical part in relation to another in a manner such that the detent can be released by force applied to one of the parts. For example, support member 140 may comprise a detent 162 maintained within bore 164 under spring force such that detent 162 is biased outward from bore 164 toward first clamping pad 142a. Bore 164 may include a collar or other device at the outward edge of the bore to maintain detent 162 within bore 164. First clamping pad 142a may include a plurality of recesses 166 positioned to engage with detent 162 as first clamping pad 142a rotates about axis of rotation 152, recesses 166 positioned such that when engaged with detent 162, a side of stack 118 is oriented substantially parallel with plane 130 of screen 108. For example, in apparatus designed to accommodate display substrates with four sides, first clamping pad 142a can include four recesses arranged at 90-degree intervals (e.g., 0 degrees, 90 degrees, 180 degrees, 270 degrees) so that as stack 118 is rotated about axis of rotation 152, detent 162 engages with first clamping pad 142a to orient stack 118 in predetermined intervals, e.g., 90-degree intervals such that a side of the stack is oriented parallel with plane 130. In some embodiments, detent mechanism 160 may be unnecessary. For example, if one or both clamping pads is coupled to a motor, e.g., stepper motor, a motor controller in communication with the motor may be configured to stop rotation of the stack at predetermined angular orientations, maintaining the selected predetermined orientation until further rotation is initiated by the motor controller. In still other embodiments, the motor may be used in conjunction with a detent mechanism.

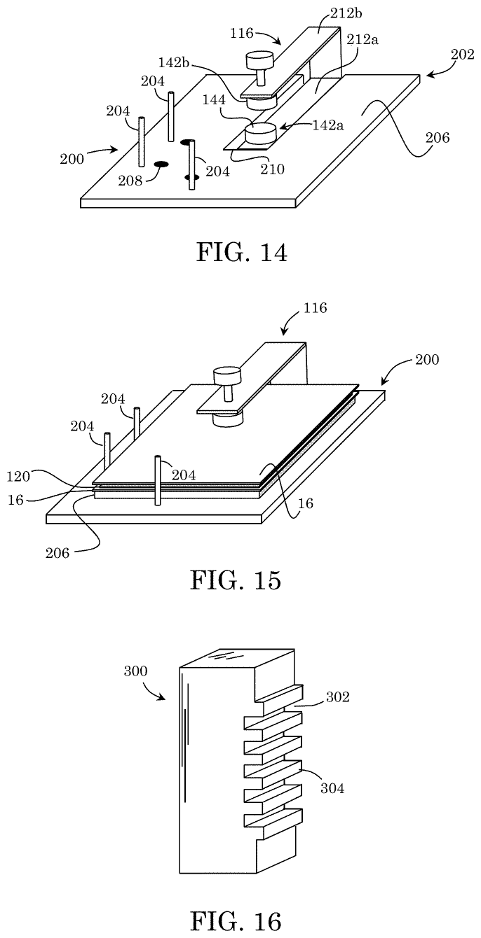

Stack 118 can be assembled using a suitable stacking jig. For example, FIG. 14 depicts an exemplary stacking jig 200 for assembling stack 118, stacking jig 200 comprising a base 202 and a plurality of alignment pins 204. For example, in some embodiments, stacking jig 200 may comprise at least three alignment pins, the alignment pins extending from upper major surface 206 of base 202. In embodiments, alignment pins 204 can extend orthogonally from major surface 206. In the embodiment depicted in FIG. 14, stacking jig 200 can comprise side alignment pins, and an end alignment pin. Base 202 may further define a plurality of holes 208 into which alignment pins 204 can be inserted to allow rearrangement of the alignment pins to accommodate multiple stack dimensions. Moreover, in the embodiment depicted in FIG. 15, base 202 may further comprise a slot 210 sized to accommodate at least a portion of rotary fixture 116. For example, in embodiments, rotary fixture 116 may be U-shaped, wherein support member 140 comprises opposing arms 212a, 212b that cooperate with axle 148 and threaded rod 154. Accordingly, slot 210 can be sized to receive an arm of rotary fixture 116 (e.g., arm 212a) to which first clamping pad 142a is coupled. In the illustrated stacking jig, a thickness of base 202 can be configured such that first clamping surface 144 of first clamping pad 142a is coplanar with major surface 206 of base 202.

Referring now to FIG. 15, to assembly stack 118, rotary fixture 116 is engaged with base 202 by inserting the appropriate arm of support member 140 (e.g., arm 212a) into slot 210. Second clamping pad 142b is moved away from first clamping pad 142a, for example, by rotating threaded rod 154 in the appropriate direction (e.g., counter clockwise) to allow room to insert display substrates and spacers between the arms of the rotary fixture. First platen 122a is placed on major surface 206 and moved such that a first edge surface of first platen 122a contacts a set of alignment pins 204. First platen 122a may comprise a recess 220 provided on a surface thereof, recess 220 sized and configured to receive (e.g., engage with) first clamping pad 142a to aid in positioning first platen 122a and avoid movement of first platen 122a relative to first clamping pad 142a. For example, in some embodiments, first clamping pad 142a may be circularly cylindrical, wherein first platen 122a can comprise a complementarily-sized circularly cylindrical recess 220. Other clamping pad and platen recess shapes can be used, such as oval, rectangular (e.g., square), triangular, and so forth). First platen 122a can be further moved such that an additional alignment pin 204 contacts another (e.g., adjacent) edge surface of first platen 122a orthogonal to the first edge surface. First platen 122a functions to evenly transfer force applied to display tiles 14 without bending of the tile substrates that could lead to fracture of the tile substrates. Thus, first platen 122a should be configured to provide adequate flatness and rigidity. For example, in some embodiments, first platen 122a can be formed of a suitable metal, for example aluminum or stainless steel.

With first platen 122a in place, a first display tile 14 can be positioned on first platen 122a such that edge surfaces 30 of the first tile substrate extend outward from corresponding edge surfaces of first platen 122a. That is, so that edge surfaces of the first platen are recessed relative to corresponding edge surfaces 30 of the first tile substrate. A suitable recess depth D4 (See FIG. 11) can be in a range from about 0 μm to about 100 μm. Next, a first spacer 120 can be positioned on the first display tile, again, making sure that proper alignment and positioning of the corresponding edge surfaces of the platen, spacer, and display substrate is maintained. The length and width dimensions of the spacer should be less than corresponding dimensions of the adjacent display tile so that edge surfaces of the spacer are recessed relative edge surfaces of the display tile by distance D3. A template block, such as template block 300 illustrated in FIG. 16, can be used to ensure proper platen edge surface-to-spacer edge surface-to-display substrate edge surface positioning. That is, template block 300 can be used to maintain a consistent relationship between the edge surfaces of the platens, edge surfaces of the display tiles, and edge surfaces of the spacers during stack assembly. Template block 300 can comprise alternating recesses 302 and teeth 304 that position edge surfaces of the display substrates and edge surfaces of the spacers relative to each other with predetermined offsets according to, for example, D3. Spacers 120 should be sized and positioned so edge surfaces of the spacers are recessed a distance D3 in a range from about 1 mm to about 3 mm from corresponding edge surfaces of the display tiles. Multiple template blocks can be used if needed. Once the first spacer 120 and the first display tile 14 are positioned according to predetermined offsets, the operation is repeated until all spacers and display tiles to be included in the stack have been added, at which time second platen 122b can be added to the stack and threaded rod 154 rotated to clamp the stack between respective clamping pads 142a, 142b and platens 122a, 122b. As with first platen 122a, second platen 122b may comprise a recess 220 provided on an outward-facing surface (away from stack 118), the recess sized and configured to receive (e.g., engage with) second clamping member 142b to aid in positioning second platen 122a and avoid movement of the second platen relative to second clamping member 142b. For example, in some embodiments, second clamping member 142b may be circularly cylindrical, wherein second platen 122b can comprise a complementarily-sized circularly cylindrical recess 220. Other clamping member and platen recess shapes can be used, such as oval, rectangular (e.g., square), triangular, and so forth).

Although the preceding process for adding display substrates and spacers is described starting with a tile substrate adjacent the platens, in some embodiments, the process can start and end with a spacer adjacent the platens. Rotary fixture 116 can be removed from stacking jig 200 once stack 118 is clamped in rotary fixture 116.

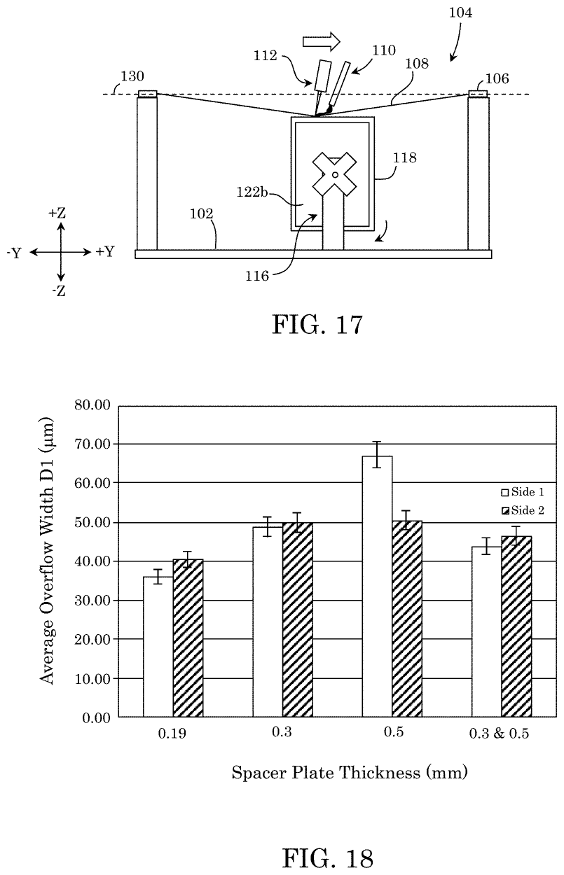

Referring now to FIG. 17, and as noted previously, coating apparatus 100 can comprise base 102, screen assembly 104 comprising frame 106 and screen 108 mounted therein, a coating material delivery system 110 for delivering coating material to screen 108, a squeegee assembly 112 for extruding coating material through screen 108, and rotary fixture 116 configured to hold stack 118 of display tiles 14 and orient the stack of display tiles, for example rotate the display tiles about an axis of rotation orthogonal to major surfaces of the display tiles, for application of coating material to edge surfaces of the tile substrates. After removal of rotary fixture 116 from stacking jig 200, rotary fixture 116 can be mounted to base 102. To accommodate different display substrate sizes, in some embodiments rotary fixture 116 can be mounted to base 102 by an intermediate platform (not shown) capable of movement in a vertical direction “z” relative to base 102, thereby allowing a vertical height of rotary fixture 116, and stack 118 clamped therein, to be adjusted relative to plane 130. In some embodiments, such intermediate platform can be an x-y-z stage capable of movement in three orthogonal directions. However, in further embodiments, screen assembly 104 may be moved along the vertical axis to accommodate different size display tiles. In still other embodiments, adjustments to both rotary fixture 116 and frame 106 may be made. In either case, rotary fixture 116 and/or screen 108 can be oriented so display tile edge surfaces of one face of the stack are substantially parallel with base 140, and screen assembly 104 adjusted so that plane 130 is parallel with the upward-facing face of stack 118.

Screen 108 can then be wetted with coating material by dispensing coating material from coating material delivery system 110. In some embodiments, it may be necessary to screen print to a surrogate material before printing to the stack, for example paper, to ensure screen 108 is fully wetted. Print quality on the paper can be evaluated for this determination.

Once a determination has been made that the screen is fully wetted and printing is satisfactory, a first side of stack 118 can be printed by operating squeegee assembly 112 to move the squeegee across the screen in a direction parallel with a length direction of the display substrate edge surfaces while applying a downward force on the screen with the squeegee. The squeegee blade can be oriented at an angle relative to plane 130, for example a 45-degree angle, although other angles may be used as necessary to achieve a consistent coating layer.

When the edge surfaces of one side of the stack have been printed, the stack can be rotated by rotating platens 122a, 122b (via threaded rod 154) to orient a second face of the stack to be substantially parallel with the screen plane and the squeegee once again traversed across the screen to apply coating material to the second set of display substrate edge surfaces. This process is repeated until all edge surfaces needing a coating layer are coated with coating material. There is no need to cure the coating material after each application of the coating material to the edge surfaces. Cure of the coating material can be performed after all edge surfaces have been coated in a manner consistent with the coating material manufacturer's directions. For example, if the coating material is a thermally-cured coating material, thermal curing (e.g., time and temperature) can be carried out in accordance with the coating material manufacturer's instructions. If the coating material is a UV-curable coating material, UV curing can be accomplished similarly (e.g., according to the coating manufacturer's recommended practices.

If, after screen printing the display substrates of a first stack additional stacks are desired to be printed, the procedure described above can be repeated. Print to paper may be performed after printing each stack to ensure the ink is uniformly applied to a subsequent stack (e.g., the screen is fully wetted and clogging of the screen has not occurred).

### EXAMPLES

Experiments were conducted to assess the impact of spacer thickness on coating layer overflow width D1. Both glass and polyethylene terephthalate glycol spacers were sandwiched between glass tile substrates in a stack held by a rotary fixture 116 as described herein, the spacers having thicknesses varying between 0.19 mm, 0.3 mm and 0.5 mm. In one such experiment, a mix of 0.3 mm and 0.5 mm thick spacers were used. An epoxy ink, Wayglo FC-725 from Chime Mien Ink Chemical Company, Ltd., with 15% by weight FC-182 thinner and 10% by weight FC-941 Catalyst (hereinafter “Wayglo”), was applied to the edge surfaces of the tile substrates in accordance with methods described herein. The resultant coating layer was cured at 150° C. for 30 minutes, and the coating layer overflow measured. Thickness of the coating layer was measured with an optical scattering instrument and overflow was measured using an optical microscope. The results are plotted in FIG. 18, wherein the data show increasing overflow as spacer thickness increased. Spacers with a thickness of 0.19 mm spacer produced at least 12% to 45% smaller overflow when compared with the 0.3 mm, 0.5 mm, and a mix of the 0.3 mm and 0.5 mm spacers. Additionally, greater variation in the shape of the terminal overflow edge was observed with 0.19 mm spacers, with overflow resulting from 0.19 mm spacers exhibiting increased waviness and occasional gaps.

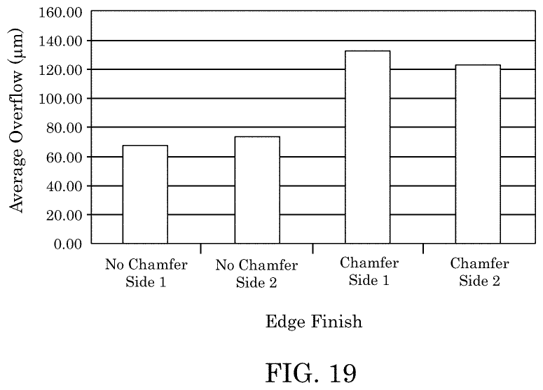

An experiment was conducted to determine the impact of chamfer on overflow width D1. A plurality of 0.5 mm spacers were sandwiched in an alternating arrangement between 100 tile substrates with unchamfered edge surfaces in a stack held by a rotary fixture 116 as described herein. Wayglo was applied to the edge surfaces of the tile substrates in accordance with methods described herein. The resultant coating layer was cured at 150° C. for 30 minutes, and the coating layer overflow measured using an optical microscope. The results are plotted in FIG. 19, wherein the data show increased overflow with chamfered edge surfaces compared to unchamfered edge surfaces. Greater overflow was measured in case of the chamfered tile substrates. In addition, overflow length in single substrate tile was shown to be controllable with an unsymmetrical chamfer length on Side-A (Side-1) and B (Side-2) of each tile. A larger (e.g., deeper) chamfer produced increased overflow.

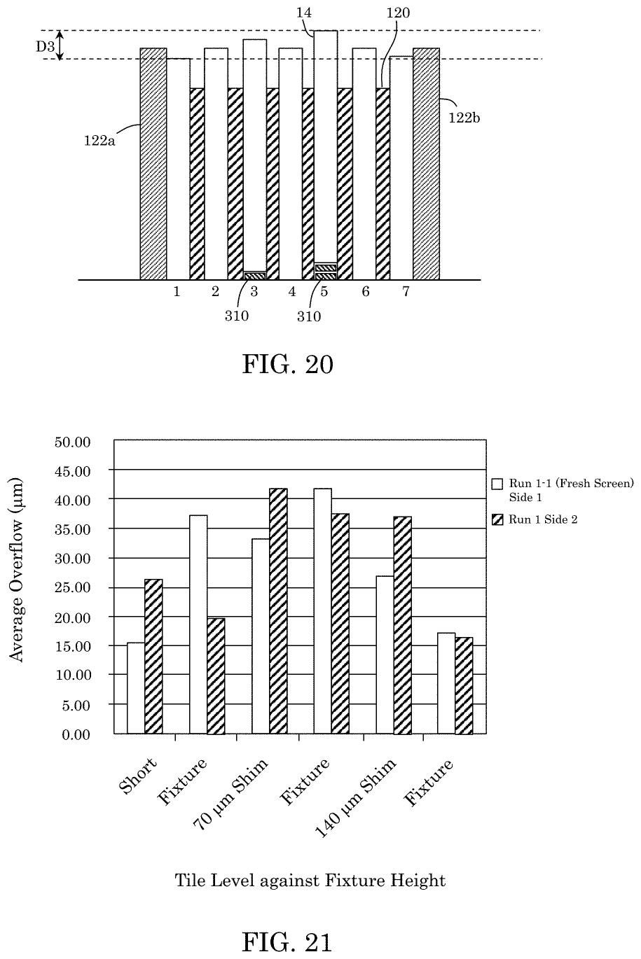

An experiment was conducted to assess the impact of tile substrate-spacer alignment (e.g., offset) on coating layer overflow width D1. In a first experiment, seven tile substrates were stacked in an alternating arrangement with six 0.5 mm-thick spacers, the resultant stack held by a rotary fixture 116 as described herein. The tile substrates were arranged such that several tile substrates were shorter than adjacent tile substrates (e.g., recessed below the adjacent tile substrates) and several tile substrates were raised with shims 310 to be higher than the adjacent tile substrates. The arrangement of tile substrates is shown in FIG. 20, wherein tile substrates 1 and 7 were lower than adjacent tile substrate 2 and 6, respectively (and also lower than the respective platens 122a and 122b). Tile substrate 3 was raised with a 70 μm shim and tile substrate 5 was raised with two 70 mm shims (for a total height of 140 mm relative to adjacent tile substrates 4 and 6. In addition, tile substrates 1 and 7 comprises chamfered edge surfaces. Wayglo was applied to the edge surfaces of the tile substrates in accordance with methods described herein. A fresh screen was employed, wherein the screen was not previously used in a coating process. The resultant coating layer was cured at 150° C. for 30 minutes, and the coating layer average overflow measured using a Zygo optical scattering instrument and overflow was measured with an optical microscope. The results are plotted in FIG. 21. The term “fixture” along the horizontal axis refers to tile substrates at the platen height, “short” refers to tile substrates recessed relative to adjacent tile substrates. The data show a decreased overflow width D1 for tile substrates that were short, with increased overflow width for raised (shimmed) tile substrates. The data also show an ability to control edge coverage and overflow width D1 with specific of tile substrate offset. In general, it was demonstrated that substrate tiles with higher than or similar height as the fixture (platen) level are better covered with ink along the edges than tiles that are shorter in height. For taller tiles, defects in coating coverage were observed due to presence of contamination and possibly de-wetting of coating material. High (e.g., “proud”) tile substrate edge surfaces coated better than shorter tiles. It was also observed that substrate tiles positioned adjacent shorter tiles showed poorer coverage than substrate tiles positioned next to taller tiles. The results demonstrated that tile substrate alignment in the stack can drive quality of the coating layer. For example, a tile that protrudes significantly from its neighboring tiles will tent the screen so that neighboring tiles will have less contact with the screen and hence shorter tiles may not be coated.

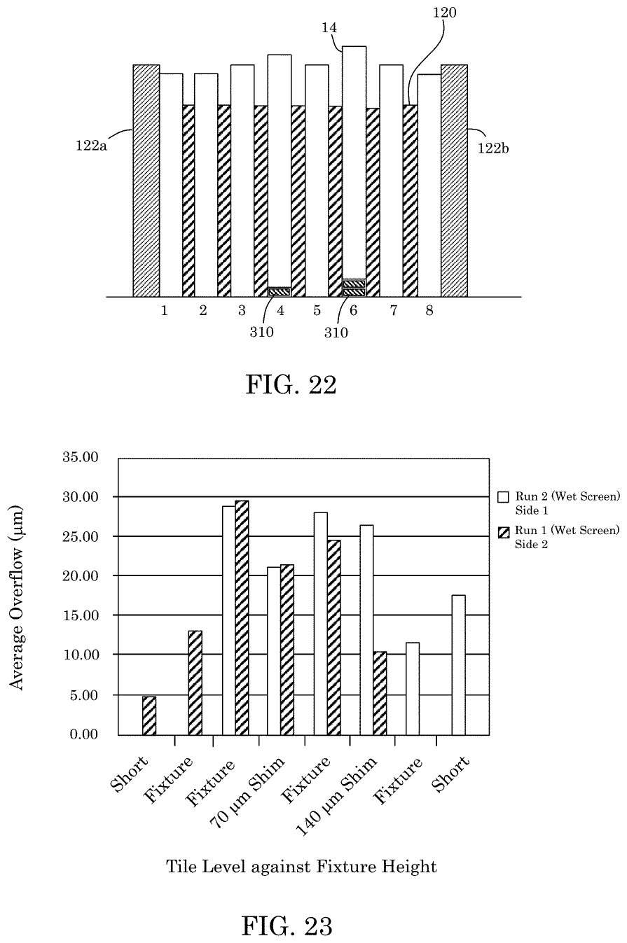

Another experiment was conducted to assess the impact of tile substrate-spacer alignment (e.g., offset) on coating layer overflow width D1. In a first experiment, eight tile substrates were stacked in an alternating arrangement with seven 0.5 mm-thick spacers, the resultant stack held by a rotary fixture 116 as described herein. The tile substrates were arranged such that several tile substrates were shorter than adjacent tile substrates (e.g., recessed below the adjacent tile substrates) and several tile substrates were raised with shims 310 to be higher than the adjacent tile substrates. The arrangement of tile substrates is shown in FIG. 22, wherein tile substrates 1, 2 and 8 were lower than adjacent tile substrates 3 and 7, respectively (and also lower than the respective platens 122a and 122b). Tile substrate 4 was raised with a 70 μm shim and tile substrate 6 was raised with two 70 mm shims (for a total height of 140 mm relative to adjacent tile substrates 5 and 7). In addition, tile substrates 1, 2, and 8 comprised chamfered edge surfaces. Wayglo was applied to the edge surfaces of the tile substrates in accordance with methods described herein. A wetted screen was employed, wherein the screen was fully wetted by coating material. The resultant coating layer was cured at 150° C. for 30 minutes, and the coating layer average overflow measured. The results are plotted in FIG. 23. The term “fixture” along the horizontal axis refers to tile substrates at the platen height, “short” refers to tile substrates recessed relative to adjacent tile substrates.

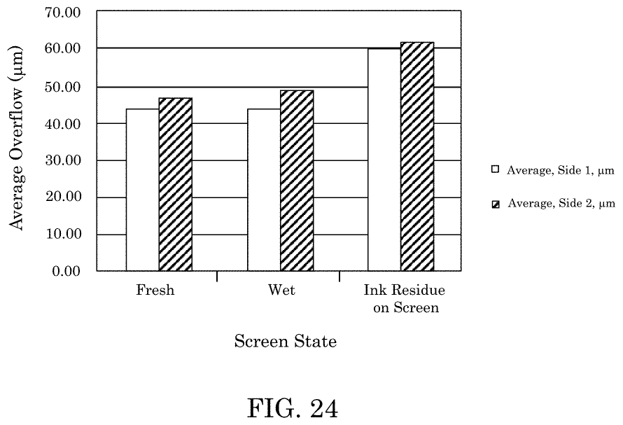

Additional experiments were conducted to assess the impact of screen state on coating layer overflow width D1. In a first experiment, a plurality of tile substrates were stacked in an alternating arrangement with 0.5 mm-thick spacers, the resultant stack held by a rotary fixture 116 as described herein. Wayglo was applied to the edge surfaces of the tile substrates in accordance with methods described herein using a fresh screen, wherein the screen did not contain coating material prior to printing to the edge surfaces. The resultant coating layer was cured at 150° C. for 30 minutes, and the coating layer average overflow measured as in previous experiments. In another experiment, another plurality of tile substrates (up to 100 tile substrates) was stacked in an alternating arrangement with 0.5 mm-thick spacers, the resultant stack held by a rotary fixture 116 as described herein. Wayglo was applied to the edge surfaces of the tile substrates in accordance with methods described herein using a screen fully wetted with the coating material. That is, the screen was used to print to paper seven times prior to printing to the tile substrate edge surfaces to ensure a fully wetted screen. The resultant coating layers were cured at 150° C. for 30 minutes, and the coating layer average overflow measured. In still another experiment, another plurality of tile substrates was stacked in an alternating arrangement with 0.5 mm-thick spacers, the resultant stack held by a rotary fixture 116 as described herein. Wayglo was applied to the edge surfaces of the tile substrates in accordance with methods described herein using a screen comprising ink residue from a previous printing operation. The resultant coating layer was cured at 150° C. for 30 minutes, and the coating layer average overflow measured as previously described. The data from these experiments is presented in FIG. 24. Edge surfaces obtained from the fresh-screen printing experiment displayed very wavy terminal edges, including gaps. Edge surfaces from the fully-wetted experiment exhibited wavy terminal edges but no gaps, while edge surfaces printed with a screen comprising coating material residue were significantly less wavy than the wetted-screen results, with an increased overflow width in a range from about 32% to about 36%. Accordingly, it was found that screen wetting can be an important variable, but within limits. Over-wetting can cause ink accumulation behind the screen and may cause excess overflow. The wetting process ensures the ink penetrates through the screen mesh without accumulation of ink on the back-side of the screen.

It will be apparent to those skilled in the art that various modifications and variations can be made to embodiments of the present disclosure without departing from the spirit and scope of the disclosure. For example, the substrates coating in accordance with embodiments disclosed herein may be used for other purposes and is not confined to display apparatus. Thus, it is intended that the present disclosure cover such modifications and variations provided they come within the scope of the appended claims and their equivalents.

1. A glass article comprising a glass substrate including a first major surface, a second major surface opposite the first major surface, and at least one edge surface extending between and connecting the first major surface to the second major surface, the glass substrate further comprising a coating material deposited as a contiguous coating layer on the at least one edge surface and at least a portion of the first major surface or the second major surface along and proximate the at least one edge surface, the coating layer extending an overflow distance on the at least a portion of the first major surface or the second major surface in a range from equal to or greater than about 25 micrometers to equal to or less than about 170 micrometers.

2. The glass article of claim 1, wherein a thickness of the coating layer is equal to or less than about 100 micrometers.

3. The glass article of claim 1, wherein the coating material comprises an epoxy.

4. (canceled)

5. (canceled)

6. (canceled)

7. The glass article of claim 1, wherein a bulk resistivity of the coating material is equal to or greater than about 1×10⁸ ohm.

8. The glass article of claim 1, wherein a bulk resistivity of the coating material is equal to or greater than about 1×10¹⁵ ohm.

9. The glass article of claim 1, wherein a surface roughness Sa of the coating layer is equal to or less than about 250 nanometers.

10. The glass article of claim 1, wherein an optical density of the coating layer is equal to or greater than about 1.8.

11. (canceled)

12. (canceled)

13. The glass article of claim 1, wherein the at least one edge surface comprises a plurality of edge surfaces, the contiguous coating layer coating each edge surface.

14. The glass article of claim 1, wherein a thickness of the glass substrate is in a range from about 300 micrometers to about 1.3 millimeters.

15. The glass article of claim 1, wherein the at least one edge surface comprises an arcuate surface.

16. The glass article of claim 1, further comprising an electrical conductor extending across the at least one edge surface from the first major surface to the second major surface, the coating layer disposed over the electrical conductor.

17. The glass article of claim 16, further comprising an electronic device deposited on the first major surface and in electrical communication with the electrical conductor.

18. The glass article of claim 17, wherein the electronic device comprises an electroluminescent element.

19. The glass article of claim 18, wherein the electroluminescent element comprises a light emitting diode.

20. A method of coating a glass substrate, comprising:
positioning a plurality of glass substrates and a plurality of spacers in an alternating relationship to form a substrate stack, each glass substrate comprising a first major surface, a second major surface, a first edge surface extending between and connecting the first major surface and the second major surface, and a second edge surface extending between and connecting the first and second major surfaces;
clamping the substrate stack between a first platen and a second platen in a fixture;
mounting the fixture beneath a screen, the clamped substrate stack rotatable in the fixture about an axis of rotation orthogonal to the first major surface of each glass substrate, and orienting the clamped stack to a first orientation;
applying a coating material to the screen;
forcing a squeegee onto the screen and deflecting the screen toward the first edge surfaces, traversing the squeegee across the screen in a first direction orthogonal with the axis of rotation from a start position to a stop position to apply the coating material to the first edge surfaces, and returning the squeegee to the start position;
rotating the substrate stack to a second orientation; and
forcing the squeegee onto the screen and deflecting the screen toward the second edge surfaces, traversing the squeegee in the first direction across the screen from the start position to the stop position to apply the coating material to the second edge surfaces.

21. The method of claim 20, wherein the coating material is applied to at least a portion of at least one of the first major surface or the second major surface of each glass substrate simultaneous with applying the coating to the first edge surface.

22. The method of claim 20, wherein each glass substrate comprises at least one electrical conductor extending across the first edge surface from the first major surface to the second major surface, and the coating material is applied over the at least one electrical conductor.

23. The method of claim 20, wherein the first orientation is orthogonal to the second orientation.

24. The method of claim 20, wherein each of the first platen and the second platen comprises a first major surface, a second major surface, and a first edge surface extending between and connecting the first major surface and the second major surface, the first edge surface of the first platen and the first edge surface of the second platen defining a first plane, and the first edge surfaces of the glass substrates extend outward from the first plane a distance in a range from about 10 micrometers to about 100 micrometers.

25. The method of claim 20, wherein each spacer comprises a first major surface, a second major surface, and a first edge surface extending between and connecting the first major surface and the second major surface of the respective spacer, and a distance between the first edge surface of one of the glass substrates and the first edge surface of a spacer adjacent to the one of the glass substrates is in a range from about 1 mm to about 3 mm.

26. The method of claim 20, wherein a thickness of each spacer is in a range from about 1 millimeter to about 20 millimeters.

27. The method of claim 20, wherein the coating material applied to the first edge surface of each glass substrate is not cured prior to the applying the coating material to the second edge surface of each substrate.

28. The method of claim 20, wherein each glass substrate in the substrate stack comprises at least three edge surfaces, the method further comprising coating each edge surface of each glass substrate with the coating material and curing the coating material after the coating material has been applied to all of the at least three edge surfaces.

29. The method of claim 21, wherein an overflow distance on the at least a portion of the first major surface or the second major surface is in a range from equal to or greater than about 25 micrometers to equal to or less than about 170 micrometers.
